(19) United States
(12) Patent Application Publication
(10) Pub. No.: US 2013/0065179 A1
(43) Pub. Date: Mar. 14, 2013

(54) POSITIVE RESIST COMPOSITION AND PATTERNING PROCESS

(71) Applicants: Kazunori MAEDA, Jyoetsu (JP); Ryosuke TANIGUCHI, Jyoetsu (JP); Seiichiro TACHIBANA, Jyoetsu (JP)

(72) Inventors: Kazunori MAEDA, Jyoetsu (JP); Ryosuke TANIGUCHI, Jyoetsu (JP); Seiichiro TACHIBANA, Jyoetsu (JP)

(73) Assignee: SHIN-ETSU CHEMICAL CO., LTD., Tokyo (JP)

(21) Appl. No.: 13/604,258

(22) Filed: Sep. 5, 2012

(30) Foreign Application Priority Data
Sep. 12, 2011 (JP) 2011-198478

(51) Int. Cl. G03F 7/004; G03F 7/20

(52) U.S. Cl. 430/270.1; 430/326

(57) ABSTRACT

There is disclosed a positive resist composition comprising (A) a specific resin (B) a photo acid generator, (C) a basic compound, and (D) a solvent. There can be a positive resist composition having, in a photolithography using a high energy beam such as an ArF excimer laser beam as a light source, an excellent resolution, especially excellent depth of focus (DOF) characteristics with an excellent pattern profile, and in addition, in formation of a contact hole pattern, giving a pattern having excellent circularity and high rectangularity; and a patterning process using this positive resist composition.

### BACKGROUND OF THE INVENTION

1. Field of the Invention

The present invention relates to a positive resist composition and a patterning process using the same.

2. Description of the Related Art

In recent years, as LSI progresses toward higher integration and further acceleration in speed, miniaturization of a pattern rule is required; under such a trend, development of a miniaturization process technology which uses a far UV lithography and a vacuum UV lithography is being energetically carried out. A photolithography which uses a KrF excimer laser beam of 248 nm as a light source has already been playing a key role in the actual production of a semiconductor device; and a photolithography which uses an ArF excimer laser beam of 193 nm as a light source is being used in the actual production with a fine processing. In the ArF excimer laser lithography, development of an immersion exposure process, wherein a liquid having a high refractive index intervenes between a resist coat film and a projection lens to further improve a resolution, has also been carried out. By an ArF immersion exposure instrument equipped with a projection lens having a numerical aperture (NA) of more than 1.0, processing of a pattern pitch whose size is less than the wavelength thereof is carried out; and thus, a resist composition corresponding to this is considered to be necessary (Proc. SPIE Vol. 5040, p. 724).

As to a base resin for a KrF resist composition, a polyhydroxy styrene resin which contains a phenolic hydroxyl group as an alkaline-soluble functional group has already become a substantial standard thereof. In a base resin for an ArF resist composition, a poly(meth)acrylate resin whose carboxyl group is used as an alkaline-soluble group and a resin which uses, as a polymerization unit, an alicyclic olefin such as norbornene have been investigated. Among them, a poly(meth)acrylate is considered to be a viable candidate for practical use because of its easiness in polymerization. However, in the case of the resist resin which uses these carboxyl groups having higher acidity than a phenolic hydroxyl group as an alkaline-soluble functional group, control of dissolution is a problem because a pattern fall may occur readily by swelling and so forth. To reduce swelling, decreasing lipophilicity of a base resin is effective; and it is known that lipophilicity can be decreased thereby enabling to ameliorate LWR by using a unit having the soluble carboxylic acid group thereof protected by a monocyclic acid labile group. However, when a base resin whose lipophilicity is decreased is used, a dissolution contrast thereof is insufficient whereby causing a problem of insufficient rectangularity in a fine pattern.

In these compositions, to satisfy both resolution and circularity in formation of a contact hole pattern is difficult. Especially in the case of forming a contact hole pattern under the condition of a thicker resist film as compared with a pattern size (under the condition of a high aspect ratio), resolution is very important. In a conventional poly(meth)acrylate polymer, formation of the contact hole pattern is possible by increasing a heat-treatment temperature after photo-exposure. However, this facilitates acid diffusion thereby causing a problem of circularity deterioration.

In addition, as requirement of a higher resolution increases further, betterment of various lithography properties is required. In particular, characteristic improvement in depth of focus (DOF) is required to increase a process margin and so forth during patterning.

### SUMMARY OF THE INVENTION

The present invention was made in view of the situation mentioned above, and has objects to provide; a positive resist composition having, in a photolithography using a high energy beam such as an ArF excimer laser beam as a light source, an excellent resolution, especially excellent depth of focus (DOF) characteristics with an excellent pattern profile, and in addition, in formation of a contact hole pattern, giving a pattern having excellent circularity and high rectangularity; and a patterning process using this positive resist composition.

In order to solve the problems mentioned above, the present invention provides a positive resist composition comprising (A) a resin having an alkaline-solubility thereof increased by an acid and containing a repeating unit shown by the following general formula (1-1), a repeating unit shown by the following general formula (1-2), and as repeating units having an acid labile group, at least one repeating unit shown by the following general formulae (a-1) to (a-3) and at least one repeating unit shown by the following general formulae (b-1) and (b-2), (B) a photo acid generator, (C) a basic compound, and (D) a solvent,

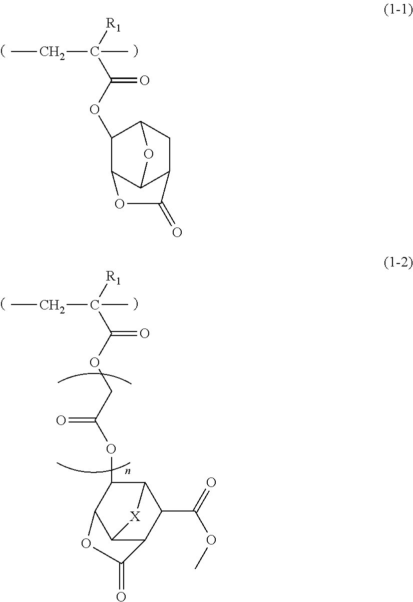

wherein R₁ and R₂ represent a methyl group or a hydrogen atom; X represents any of an oxygen atom, a sulfur atom, a methylene group, and an ethylene group; “n” represents 0 or 1;

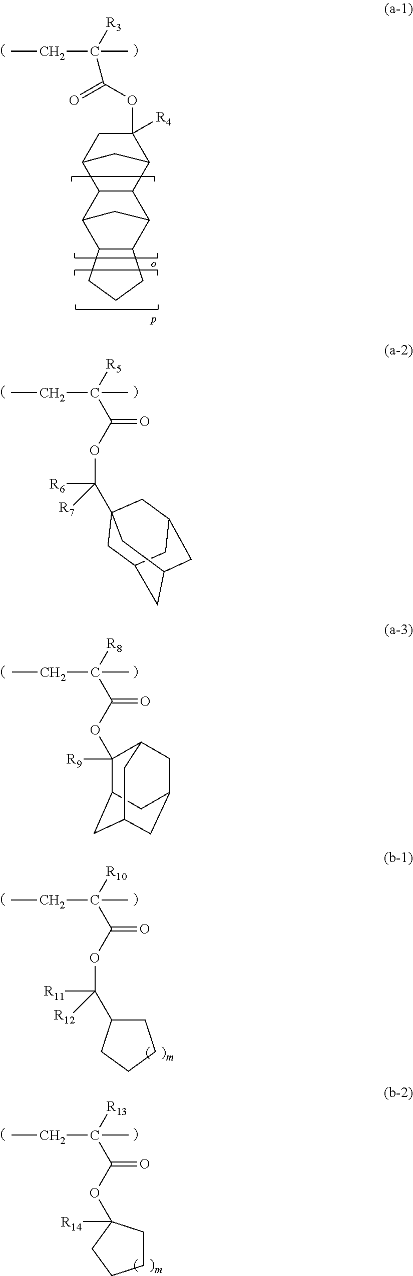

wherein R₃, R₅, R₈, R₁₀, and R₁₃ represent a methyl group or a hydrogen atom; R₄, R₆, R₇, R₉, R₁₁, R₁₂, and R₁₄ represent a linear or a branched alkyl group having 1 to carbon atoms; “o” and “p” represent o=1 and p=0, or o=0 and p=1; and “m” represents an integer of 1 to 4.

If, as mentioned above, a positive resist composition contains (A) a resin having an alkaline-solubility thereof increased by an acid (this is also referred to as the composition (A)), a positive resist composition having an excellent resolution, especially excellent depth of focus (DOF) characteristics with an excellent pattern profile, and in addition, in formation of a contact hole pattern, giving a pattern having excellent circularity and high rectangularity can be obtained.

In addition, it is preferable that the repeating units having an acid labile group and contained in (A) the resin having an alkaline-solubility thereof increased by an acid are a repeating unit shown by the following general formula (a-1)′ and a repeating unit shown by the following general formula (b-2), wherein R₃, R₁₃, R₄, R₁₄, and “m” represent the same meanings as before.

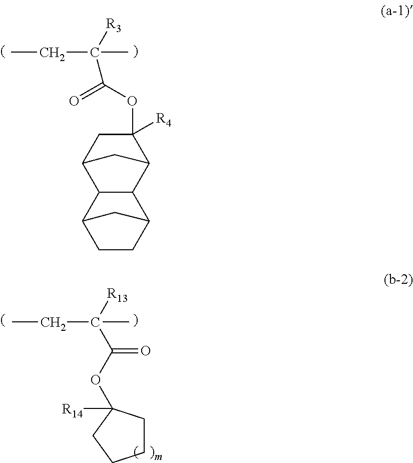

Among combinations of at least one repeating unit shown by the general formulae (a-1) to (a-3) with at least one repeating unit shown by the general formulae (b-1) and (b-2), a combination of the repeating unit shown by the general formula (a-1)′ with the repeating unit shown by the general formula (b-2) is particularly preferable.

In addition, it is preferable that (A) the resin having an alkaline-solubility thereof increased by an acid further contains a repeating unit shown by the following general formula (2), wherein R₁₅ represents a methyl group or a hydrogen atom; Y represents a single bond or a divalent organic group optionally containing at least either one of an ester bond and an ether bond; and “l” represents 1 or 2.

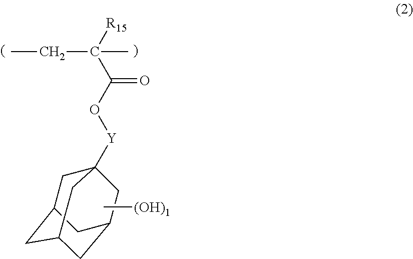

The resin of the component (A) which further contains a repeating unit having a hydroxyl group as shown by the general formula (2) can depress acid diffusion and give an even higher resolution.

In addition, it is preferable that amount of the repeating units having an acid labile group in (A) the resin having an alkaline-solubility thereof increased by an acid is 50 to 70% by mole relative to totality of the repeating units contained in (A) the resin having an alkaline-solubility thereof increased by an acid.

If a resin having the composition as mentioned above is used, a positive resist composition having an excellent resolution, especially excellent depth of focus (DOF) characteristics with an excellent pattern profile, and in addition, in formation of a contact hole pattern, giving a pattern having excellent circularity and high rectangularity can be obtained more surely.

In addition, the present invention provides a patterning process wherein the process includes a step of applying the positive resist composition onto a substrate; after heat treatment, a step of exposure to a high energy beam; and a step of development by using an alkaline developer.

According to the patterning process as mentioned above, an excellent resolution, especially excellent depth of focus (DOF) characteristics, and in addition, in formation of a contact hole pattern, a pattern having excellent circularity and high rectangularity can be obtained.

In addition, it is preferable that wavelength of the high energy beam is in the range of 180 to 250 nm. And in addition, it is preferable that the step of exposure to the high energy beam is carried out by an immersion exposure in which the exposure is done via water.

As mentioned above, the patterning process of the present invention is most suitable for fine patterning by a high energy beam of 180 to 250 nm; and in addition, it can also be used in an immersion lithography.

According to the positive resist composition and the patterning process of the present invention, in a photolithography which uses a high energy beam such as an ArF excimer laser beam as a light source, an excellent resolution, especially excellent depth of focus (DOF) characteristics with an excellent pattern profile, and in addition, in formation of a contact hole pattern, a pattern having excellent circularity and high rectangularity can be obtained.

### DESCRIPTION OF THE PREFERRED EMBODIMENTS

As mentioned above, in a photolithography which uses a high energy beam such as an ArF excimer laser beam as a light source, a positive resist composition having an excellent resolution, especially excellent depth of focus (DOF) characteristics, and in addition, in formation of a contact hole pattern, being capable of giving a pattern having excellent circularity and high rectangularity has been wanted.

Inventors of the present invention carried out an extensive investigation to achieve the objects as mentioned above, and as a result, they found that a positive resist composition containing, as (A) a resin having an alkaline-solubility thereof increased by an acid, a resin containing a combination of specific repeating units having an acid labile group such as those shown by the following general formulae (a-1) to (a-3) and (b-1) to (b-2), and in addition, a combination of specific repeating units having a lactone group such as those shown by the following general formulae (1-1) and (1-2), was extremely useful as a resist composition in a precise and fine processing because the positive resist composition was excellent in resolution and pattern rectangularity. They found especially that the positive resist composition of the present invention could give a pattern having excellent circularity and rectangularity in formation of a contact hole pattern; and based on these findings, the present invention could be accomplished.

Meanwhile, “DOF” means a range of depth of focus in which a resist pattern can be formed within an intended range of a size difference relative to the target size when photo-exposure is effected with moving a focal point up and down with the same exposure dose, that is, a range in which a resist pattern coincident with a mask pattern can be obtained; and thus, larger DOF is more preferable.

The positive resist composition of the present invention contains, as the component (A), a resin which contains a repeating unit shown by the following general formula (1-1), a repeating unit shown by the following general formula (1-2), and, as repeating units having an acid labile group, at least one repeating unit shown by the following general formulae (a-1) to (a-3) and at least one repeating unit shown by the following general formulae (b-1) and (b-2),

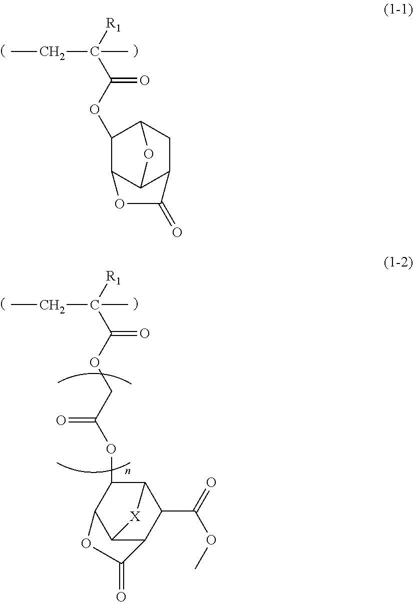

wherein R₁ and R₂ represent a methyl group or a hydrogen atom, and X represents any of an oxygen atom, a sulfur atom, a methylene group, and an ethylene group. “n” represents 0 or 1,

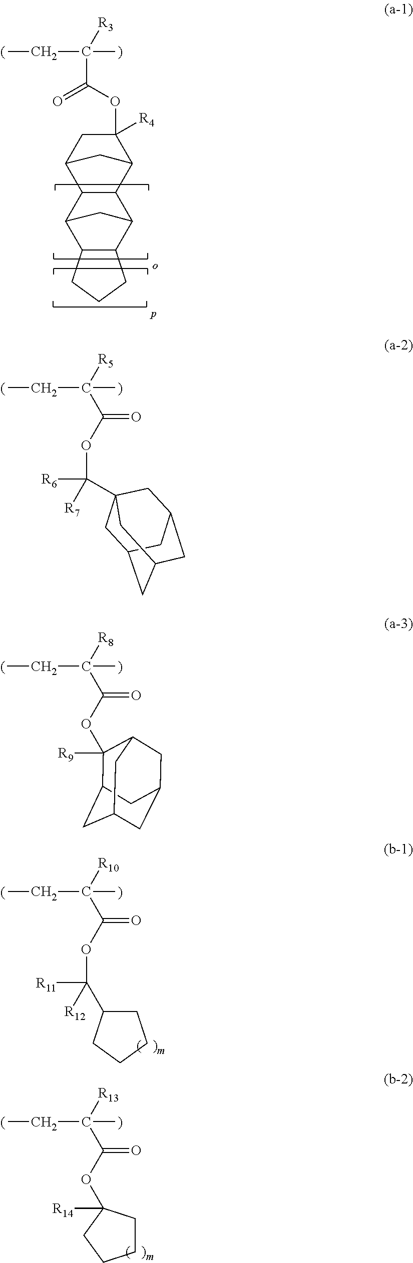

wherein R₃, R₅, R₈, R₁₀, and R₁₃ represent a methyl group or a hydrogen atom. R₄, R₆, R₇, R₉, R₁₁, R₁₂, and R₁₄ represent a linear or a branched alkyl group having 1 to 5 carbon atoms. “o” and “p” represent o=1 and p=0, or o=0 and p=1. “m” represents an integer of 1 to 4.

Specific example of R₄, R₆, R₇, R₉, R₁₁, R₁₂, and R₁₄ which represent a linear or a branched alkyl group having 1 to 5 carbon atoms includes a methyl group, an ethyl group, a propyl group, an isopropyl group, a n-butyl group, a sec-butyl group, a tert-butyl group and so on.

Component (A) of the positive resist composition of the present invention contains, as the repeating units having an acid labile group, at least one repeating unit shown by the general formulae (a-1) to (a-3) and at least one repeating unit shown by the general formulae (b-1) and (b-2), and both repeating units shown by the general formulae (1-1) and (1-2) which have a lactone group therein.

The repeating unit shown by the general formula (1-1) can suppress acid diffusion and improve resolution, but circularity is deteriorated by sole use of the repeating unit shown by the general formula (1-1) because acid diffusion is suppressed excessively low. Therefore, by utilizing an effect of controlling acid diffusion by the repeating unit shown by the general formula (1-2), performance of excellent circularity can be expressed while improving a resolution by concurrent use of the repeating unit shown by the general formula (1-1) and the repeating unit shown by the general formula (1-2). The general formulae (a-1) to (a-3) can enhance dissolution contrast and rectangularity of the form while leading to deteriorated circularity because a head part thereof is excessively large. The general formulae (b-1) and (b-2) give a form of a round head though excellent circularity can be obtained. By concurrent use of at least one repeating unit shown by the general formulae (a-1) to (a-3) and at least one repeating unit shown by the general formula (b-1) and (b-2) as an acid labile group, performance of excellent circularity can be expressed while keeping rectangularity of the form.

A positive resist composition as mentioned above can give excellent resolution, especially excellent depth of focus (DOF) characteristics with excellent pattern profile, and in formation of a contact hole pattern, a pattern having excellent circularity and high rectangularity.

On the contrary, a positive resist composition not containing even one repeating unit mentioned above causes a problem such as a round head and a large head in a pattern form; and in addition, it gives poor DOF characteristics and deteriorated circularity in formation of a contact hole pattern.

Specific examples of preferable repeating unit shown by the general formula (1-2) are shown below.

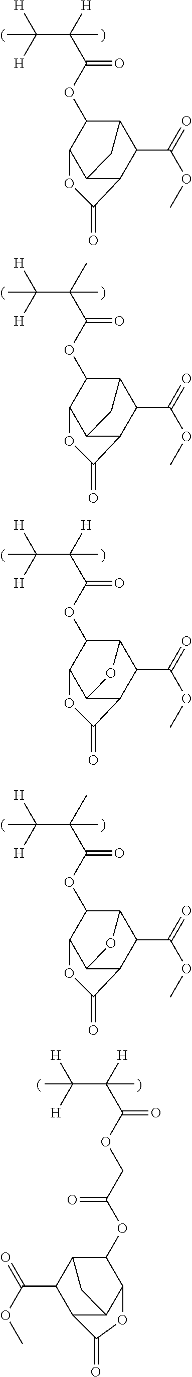

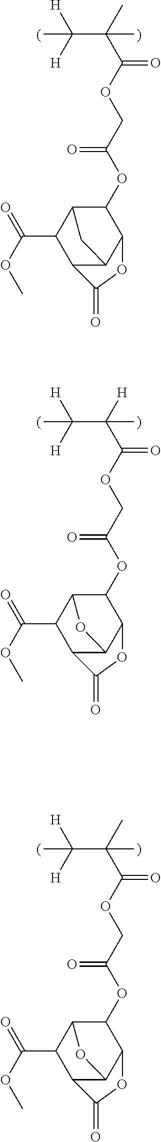

Repeating units shown by the general formulae (a-1) to (a-3), (b-1), or (b-2) in the component (A) are the repeating units whose alkaline-soluble carboxylic acid group is protected by a specific acid labile group having a polycyclic and a monocyclic alicyclic hydrocarbon structure (repeating units having an acid labile group).

Illustrative examples of the repeating unit shown by the general formulae (a-1) to (a-3) include the followings.

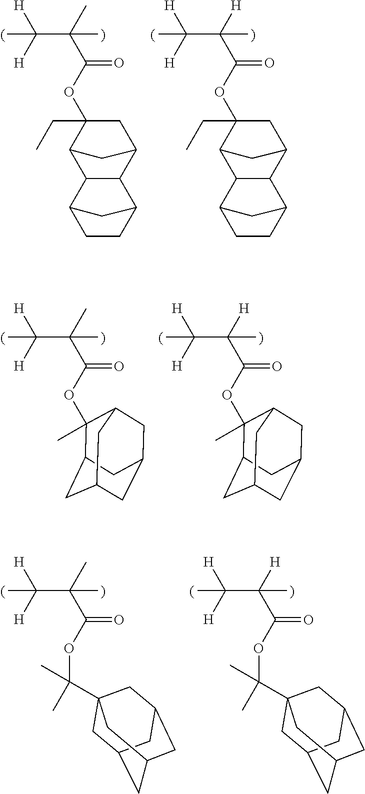

Illustrative examples of the repeating unit shown by the general formulae (b-1) to (b-2) include the followings.

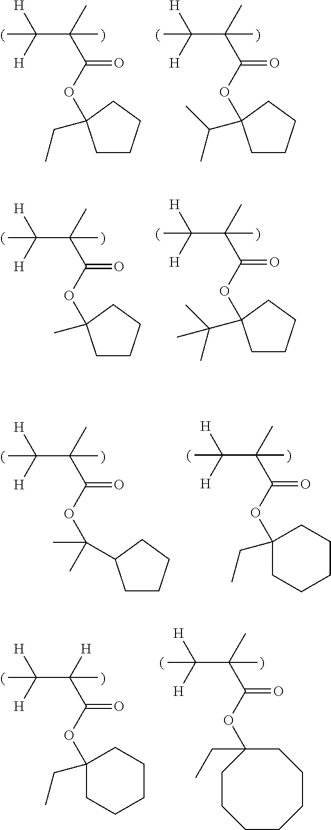

Among the combinations of at least one repeating unit shown by the general formulae (a-1) to (a-3) with at least one repeating unit shown by the general formulae (b-1) and (b-2), a combination of the repeating unit shown by the general formulae (a-1)′ with the repeating unit shown by the general formulae (b-2) is a particularly preferable combination,

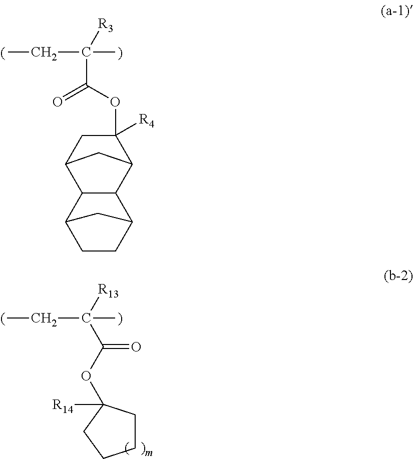

wherein R₃, R₁₃, R₄, R₁₄, and “m” represent the same meanings as before.

In addition, it is preferable that the component (A) contain further a repeating unit shown by the following general formula (2), in addition to the repeating units having an acid labile group (at least one repeating unit shown by the general formulae (a-1) to (a-3) and at least one repeating unit shown by the general formulae (b-1) and (b-2)), the repeating unit shown by the general formula (1-1), and the repeating unit shown by the general formula (1-2),

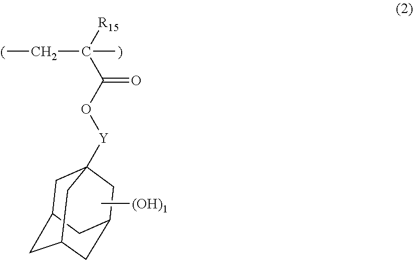

wherein R₁₅ represents a methyl group or a hydrogen atom, and Y represents a single bond or a divalent organic group optionally containing at least either one of an ester bond and an ether bond. “l” represents 1 or 2.

Illustrative examples of the repeating unit shown by the general formula (2) include the followings.

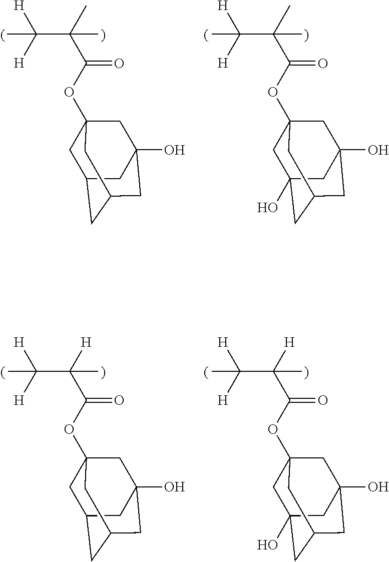

The resin of the component (A) which further contains a repeating unit having a hydroxyl group as shown by the general formula (2) can suppress acid diffusion thereby giving an even higher resolution.

As to the molecular weight of (A) the resin in the positive resist composition of the present invention, if the weight-average molecular weight (Mw) thereof is too small, dissolution thereof into water readily occurs, while if the weight-average molecular weight thereof is too large, there is a high possibility to cause decrease of an alkaline-solublity and application deficiency during the time of spin coating. From this point of view, the weight-average molecular weight thereof in terms of polystyrene equivalent by a gel permeation chromatography (GPC) is 1000 to 500000, preferably 2000 to 30000, or particularly preferably 4500 to 7000.

Amount of the repeating units having an acid labile group (at least one repeating unit shown by the general formulae (a-1) to (a-3) and at least one repeating unit shown by the general formulae (b-1) and (b-2)) in (A) the resin having an alkaline-solubility thereof increased by an acid is preferably in the range of 50 to 70% by mole relative to totality of the repeating units contained in (A) the resin having an alkaline-solubility thereof increased by an acid.

When amount of the repeating units having an acid labile group in the resin whose alkaline-solubility increases by an acid is in the range of 50 to 70% by mole, an excellent resolution, especially excellent depth of focus (DOF) characteristics with an excellent pattern profile can be obtained; and in addition, in formation of a contact hole pattern, a pattern having excellent circularity and high rectangularity can be obtained.

In synthesis of the resin of the component (A), polymerizable monomers corresponding to respective repeating units having an acid labile group (at least one repeating unit shown by the general formulae (a-1) to (a-3) and at least one repeating unit shown by the general formulae (b-1) and (b-2)) and repeating units shown by the general formulae (1-1) and (1-2), all of which are essential repeating units, and to a repeating unit shown by the general formula (2), which is an arbitrary repeating unit, are mixed; and then, polymerization is carried out by adding an initiator and a chain-transfer agent. Meanwhile, synthesis methods of respective corresponding polymerizable monomers can be referred to the Japanese Patent Laid-Open Publication No. 2008-31298, Japanese Patent Laid-Open Publication No. 2008-129389, and so on.

Meanwhile, as to the composition ratios of each repeating unit to constitute (A) the resin in the positive resist composition of the present invention, if total mole ratio of the repeating units shown by the general formula (1-1) is shown by “a %” by mole, total mole ratio of the repeating units shown by the general formula (1-2) is shown by “b %” by mole, total mole ratio of the repeating units shown by the general formulae (a-1) to (a-3) is shown by “c %” by mole, total mole ratio of the repeating units shown by the general formulae (b-1) and (b-2) is shown by “d %” by mole, and total mole ratio of the repeating units shown by the general formula (2) is shown by “e %” by mole, it is preferable that the composition ratios satisfy the following relationships:

a+b+c+d+e=100,

0<a≦30,

0<b≦30,

0<c≦50,

0<d≦50, and

0≦e≦20,

or in particular:

a+b+c+d+e=100,

10≦a≦30,

10≦b≦30,

10≦c≦50,

10≦d≦50, and

0≦e≦20.

As to (B) the photo acid generator which is contained in the positive resist composition of the present invention, any compound may be used as far as it can generate an acid by exposure to a high energy beam; and thus, any heretofore known photo acid generator used in a conventional resist composition, especially in a chemically amplifying resist composition may be used. Illustrative example of a preferable photo acid generator includes a type of a sulfonium salt, an iodonium salt, a sulfonyl diazomethane, an N-sulfonyl oxyimide, and an oxime-O-sulfonate; and these may be used singly or as a mixture of two or more of them.

Especially preferable acid generator is at least one or more kinds selected from the sulfonium salt compounds shown by the following general formula (3).

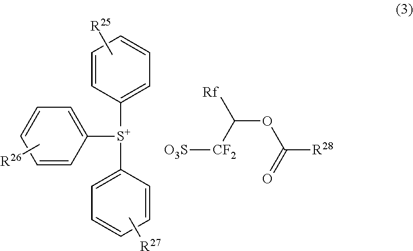

Here, each R²⁵, R²⁶, and R²⁷ independently represents a hydrogen atom, or a linear, a branched, or a cyclic monovalent hydrocarbon group having 1 to 20 carbon atoms and optionally containing a heteroatom, wherein specific example of the hydrocarbon group optionally containing a heteroatom includes a methyl group, an ethyl group, a propyl group, an isopropyl group, a n-butyl group, a sec-butyl group, a tert-butyl group, a tert-amyl group, a n-pentyl group, a n-hexyl group, a cyclopentyl group, a cyclohexyl group, an ethyl cyclopentyl group, a butyl cyclopentyl group, an ethyl cyclohexyl group, a butyl cyclohexyl group, an adamantly group, an ethyl adamantly group, a butyl adamantly group, the foregoing groups having a heteroatomic group, such as —O—, —S—, —SO—, —SO₂—, —NH—, —C(O)—, —C(═O)O—, and —C(═O)NH—, inserted between arbitrary C—C bond thereof, or the foregoing groups whose arbitrary hydrogen atom is substituted with a functional group such as —OH, —NH₂, —CHO, and —COH₂. Rf represents a hydrogen atom or a trifluoromethyl group. R²⁸ represents a linear, a branched, or a cyclic monovalent hydrocarbon group having 7 to 30 carbon atoms and optionally containing a heteroatom, wherein specific example of R²⁸ includes the followings though not limited to them.

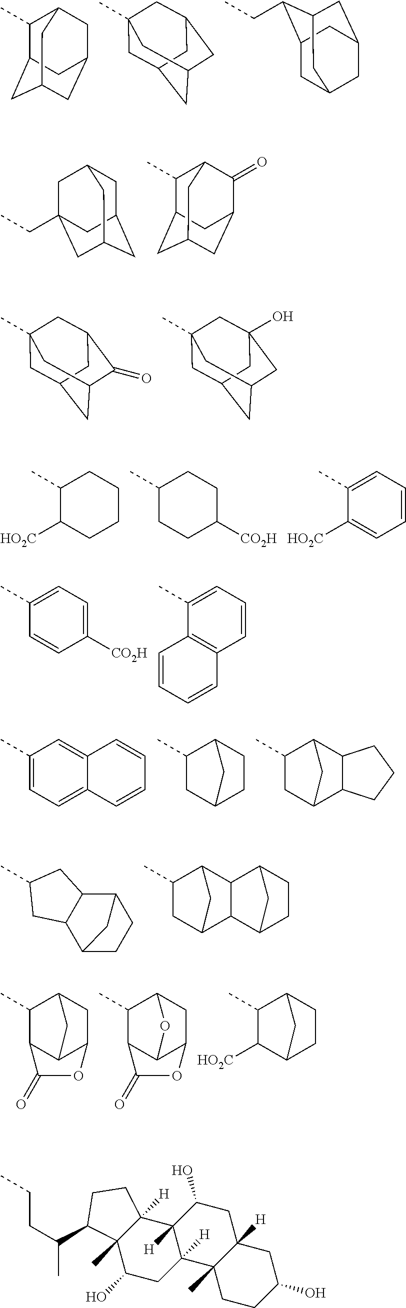

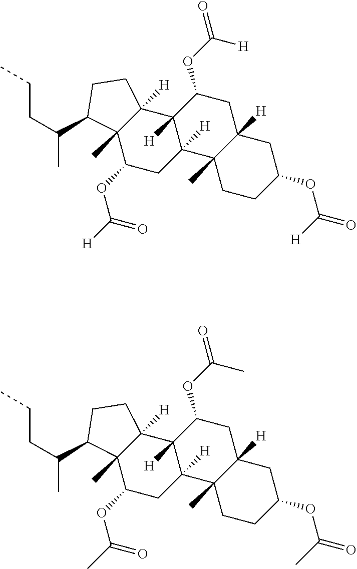

(In the formula, broken lines each represent a bonding hand.)

Specific example of further preferable composition of (B) the photo acid generator includes the followings though not limited to them.

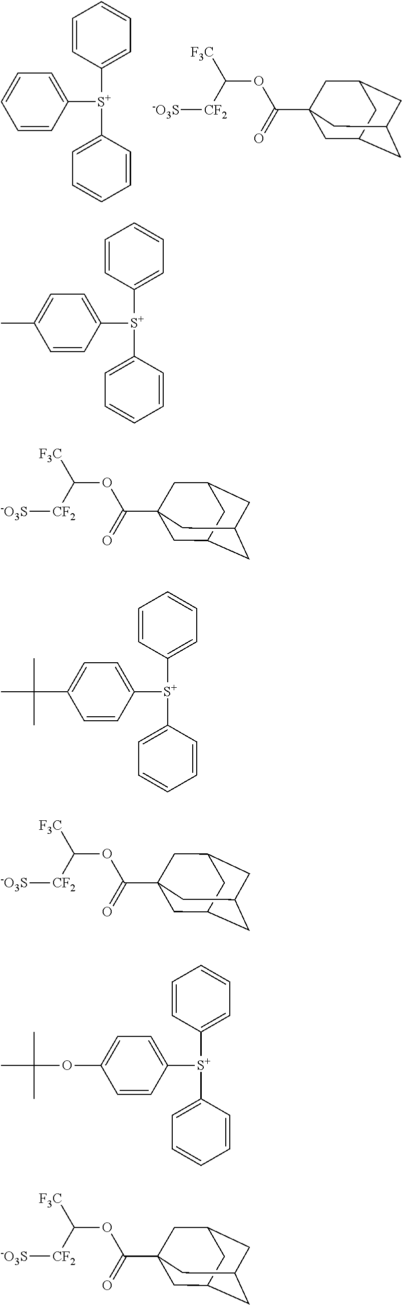

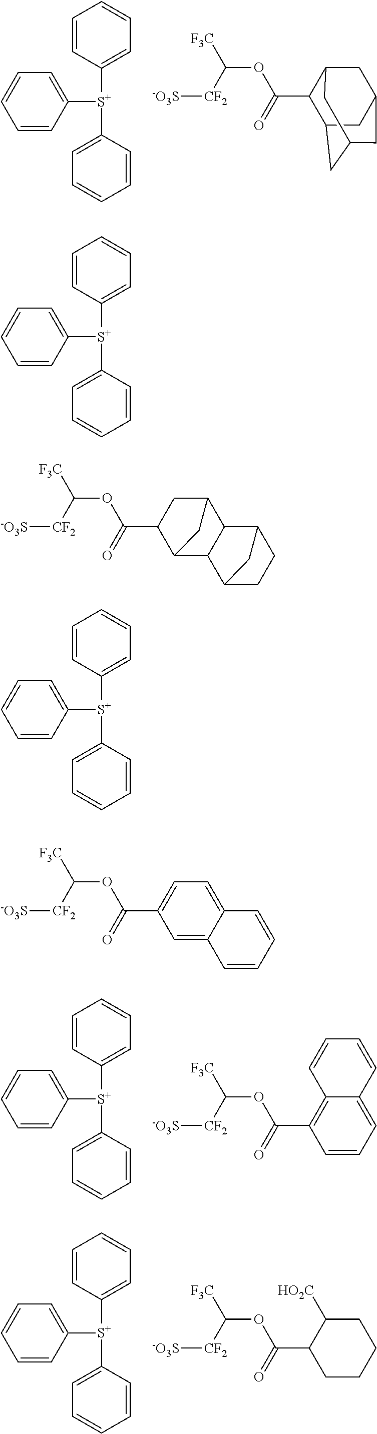

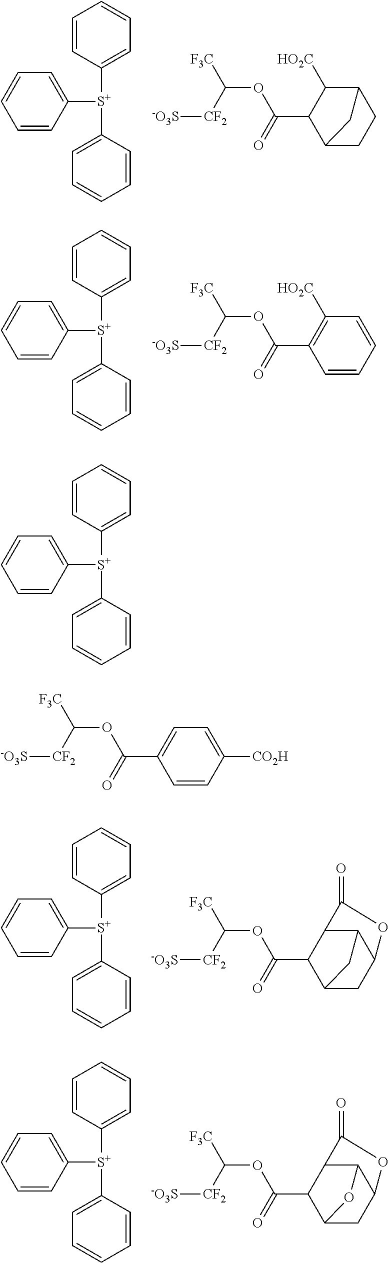

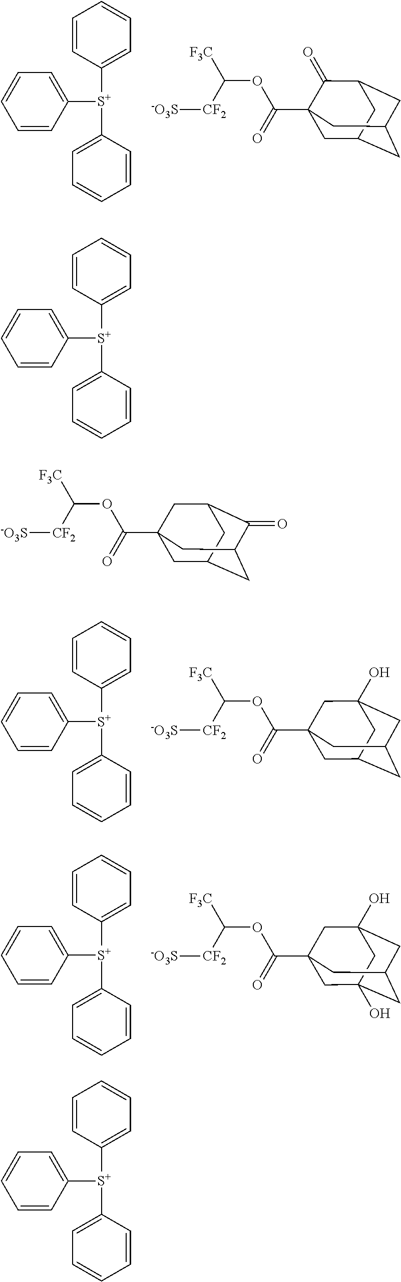

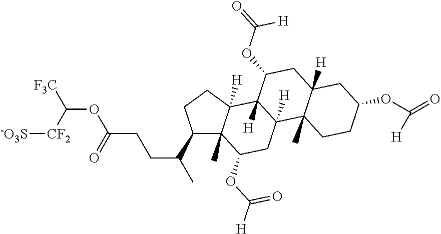

In addition, the positive resist composition of the present invention contains a basic compound as the component (C). As to this basic compound, a compound capable of suppressing diffusion rate of an acid, which is generated from an acid generator, in a resist film is suitable. When this basic compound is blended therein, diffusion rate of an acid in a resist film is suppressed thereby leading to increase in a resolution and suppress a sensitivity change after photo-exposure; and in addition, dependency on a substrate and an environment can be made small, and an exposure margin, a pattern profile, and so on can be improved.

As to the basic compound like this, any heretofore known basic compound used in a conventional resist composition, in particular, in a chemically amplified resist composition may be used, though a nitrogen-containing organic compound is especially preferable. Illustrative example of the nitrogen-containing organic compound includes a primary, a secondary, or a tertiary aliphatic amine, a mixed amine, an aromatic amine, a heterocyclic amine, a nitrogen-containing compound having a carboxy group, a nitrogen-containing compound having a sulfonyl group, a nitrogen-containing compound having a hydroxyl group, a nitrogen-containing compound having a hydroxyphenyl group, an alcoholic nitrogen-containing compound, an amide, an imide, and a carbamate.

Meanwhile, amount of the basic compound to be blended is preferably in the range of 0.001 to 4 parts by mass, or in particular 0.01 to 2 parts by mass, relative to 100 parts by mass of the base resin (component (A)). If the amount thereof is less than 0.001 parts by mass, there is no effect of blending, while if the amount thereof is more than 4 parts by mass, there is a certain case that sensitivity becomes too low.

In addition, the positive resist composition of the present invention contains a solvent as the component (D).

As to the solvent of the component (D) used in the present invention, any organic solvent may be used as far as it can dissolve a base resin, an acid generator, a basic compound, and other additives. Illustrative example of the organic solvent like this includes a ketone such as cyclohexanone and methyl ethyl ketone; an alcohol such as 3-methoxybutanol, 3-methyl-3-methoxybutanol, 1-methoxy-2-propanol, and 1-ethoxy-2-propanol; an ether such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; an ester such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol monotert-butyl ether acetate; and a lactone such as γ-butyrolactone; and these may be used singly or as a mixture of two or more of them, though not limited to these. In the present invention, cyclohexanone, diethylene glycol dimethyl ether, 1-ethoxy-2-propanol, propylene glycol monomethyl ether, and a mixed solvent of them are preferably used among the afore-mentioned organic solvents, because of excellent solubility of an acid generator among the resist components.

Amount of the organic solvent to be used can be appropriately selected in accordance with film thickness of the film to be formed, but is preferably in the range of 1000 to 5000 parts by mass relative to 100 parts by mass of the base resin.

In addition, the positive resist composition of the present invention can be added, as an arbitrary component, with a surfactant which is conventionally used to improve coating properties. Meanwhile, amount of the arbitrary component to be added may be a usually used amount.

In addition, the positive resist composition of the present invention may be added with a compound which generates an acid by decomposition with an acid (acid-proliferating compound). These compounds are described in J. Photopolym. Sci. and Tech., 8, 43 to 44 and 45 to (1955) and J. Photopolym. Sci. and Tech., 9, 29 to 30 (1996).

Illustrative example of the acid-proliferating compound includes tert-butyl 2-methyl 2-tosyloxymethyl acetoacetate and 2-phenyl 2-(2-tosyloxyethyl) 1,3-dioxolane, though not limited to them.

Patterning by using the positive resist composition of the present invention may be carried out by using a heretofore known lithography technology; and thus, patterning can be accomplished via respective steps of application, heat-treatment (prebake), photo-exposure, heat-treatment as necessary (post-exposure bake, or PEB), and development. In addition, a several steps may be added thereto.

Namely, the present invention provide a patterning process, wherein the process includes a step of applying the foregoing positive resist composition onto a substrate, after heat-treatment, a step of photo-exposure to a high energy beam, and a step of development by using an alkaline developer.

To carry out the patterning process, firstly the positive resist composition of the present invention is applied onto a substrate for manufacturing of an integrated circuit (Si, SiO₂, SiN, SiON, TiN, WSi, BPSG, SOG, organic anti-reflective coat, Cr, CrO, CrON, MoSi, and so on) by an appropriate coating method such as a spin coating, a roll coating, a flow coating, a dip coating, a spray coating, and a doctor coating in such a manner that thickness of a coated film may become 0.01 to 2.0 μm; and then, this is pre-baked on a hot plate at 60 to 150° C. for 1 to 10 minutes, or preferably at 80 to 140° C. for 1 to 5 minutes.

As the resist film becomes thinner, processing thereof becomes more difficult in view of etching selectivity with a substrate to be processed; and thus, a three-layer process having a laminate of a silicon-containing intermediate film under the resist, thereunder an underlayer film having a high carbon density and thus having a high etching resistance, and thereunder a substrate to be processed is being investigated. Here, etching selectivity between the silicon-containing intermediate film and the underlayer film is high in etching by using an oxygen gas, a hydrogen gas, or an ammonia gas; and thus, the silicon-containing intermediate film can be made thin. Etching selectivity between the monolayer resist and the silicon-containing intermediate film is also comparatively high; and thus, the monolayer resist can be made thin.

The positive resist composition of the present invention can also be used in a multi-layer resist method as mentioned above.

The underlayer film of the foregoing three-layer process may be formed by a method using coating and baking or by a method using CVD. In the case of the coating method, a resin such as a novolak resin and a resin obtained by polymerization of a monomer which contains a condensed ring and so forth is used; and in the case of the CVD method, a gas such as butane, ethane, propane, ethylene, and acetylene is used. Similarly, in the case of the silicon-containing intermediate film, a coating method and a CVD method may be used. In the coating method, silsesquioxane, a cage-type oligosilsesquioxane (POSS), and so on may be used; and in the CVD method, a variety of silane gases may be used as a raw material for it. The silicon-containing intermediate film may have an anti-reflective function that has a light absorption, or may have a light-absorbing group such as a phenyl group, or may be a SiON film. Alternatively, an organic film may be formed between the silicon-containing intermediate film and the photoresist; and in this case, the organic film may be an organic anti-reflective film. After formation of the photoresist film, rinsing with pure water may be carried out to extract an acid generator and so on from the film surface or wash-out of a particle may be carried out or a top coat may be formed thereunto.

Then, photo-exposure is carried out through a prescribed mask to form an intended pattern by using a high energy beam selected from a UV beam, a far UV beam, an electron beam, an X-ray beam, an excimer laser, a γ-beam, a synchrotron radiation beam, and so on. Exposure dose is preferably in the range of about 1 to about 200 mJ/cm², in particular about 10 to about 100 mJ/cm². Then, post-exposure bake (PEE) is carried out on a hot plate at 60 to 150° C. for 1 to 5 minutes, or preferably at 80 to 120° C. for 1 to 3 minutes. Further, development is done to form an intended pattern on a substrate by a conventional method such as a dip method, a puddle method, and a spray method for 5 to 360 seconds, or preferably for 10 to 60 seconds, by using developer of an aqueous alkaline solution such as tetramethyl ammonium hydroxide (TMAH) with the concentration thereof being in the range of 0.1 to 5% by mass, or preferably 2 to 3% by mass. Meanwhile, the positive resist composition of the present invention is suitable for fine patterning by a far UV beam of 254 to 193 nm, a vacuum UV beam of 157 nm, an extreme UV beam, an electron beam, a soft X-ray beam, an X-ray beam, an excimer laser, a γ-beam, and a synchrotron radiation beam, or more suitable by a high energy beam of 180 to 250 nm.

In addition, the positive resist composition of the present invention may be used in an immersion lithography. In an ArF immersion lithography, a liquid which has a refractive index of one or more and has a small absorption of the exposure light, such as pure water, is used as an immersion solvent. In the immersion lithography, pure water or other liquid is inserted between a lens and a resist film after prebake. With this, lens design with NA of 1.0 or more is possible so that further finer patterning may become possible. The immersion lithography is an important technology to prolong a life of the ArF lithography to the 22-nm node; and thus, development thereof is accelerated. In the immersion exposure, rinsing with pure water may be performed after exposure to remove a water droplet remained on the resist film (post-soaking), or a top coat may be formed on the resist film after prebake to avoid elution from the resist and to improve water-repellency on the film surface. As to the top coat of the resist film used in the immersion lithography, for example, a material which contains, as a base, a polymer having a 1,1,1,3,3,3-hexafluoro-2-propanol residue that is insoluble in water but soluble in an alkaline developer, and which is dissolved into an alcohol solvent having 4 or more carbon atoms, or an ether solvent having 8 to 12 carbon atoms, or mixture of them, is preferable.

### EXAMPLES

Hereinafter the present invention will be explained specifically by showing Examples and Comparative Examples. However the present invention is not restricted by these descriptions.

### <Composition and Molecular Weight of the Resins>

Composition ratios (% by mole) of repeating units to constitute the resin and molecular weight (Mw) thereof are shown in Table 1. Meanwhile, molecular weight (Mw) is the weight-average molecular weight in terms of polystyrene equivalent measured with GPC. In addition, structures of respective repeating units are shown in Table 2 and Table 3.

Meanwhile, Polymer-17 and Polymer-18 are the resins not containing the repeating units shown by the general formulae (a-1) to (a-3); Polymer-26 and Polymer-30 are the resins containing neither the repeating units shown by the general formulae (b-1) and (b-2) nor the repeating unit shown by the general formula (1-2); Polymer-27 is the resin containing neither the repeating units shown by the general formulae (a-1) to (a-3) nor the repeating unit shown by the general formula (1-1); Polymer-28 is the resin containing neither the repeating units shown by the general formulae (b-1) and (b-2) nor the repeating unit shown by the general formula (1-1); and Polymer-29 is the resin not containing the repeating unit shown by the general formula (1-1).

TABLE 1

| | Unit 1 | | Unit 2 | | Unit 3 | | Unit 4 | | Unit 5 | | |
|---|---|---|---|---|---|---|---|---|---|---|---|
| | | ratio | | ratio | | ratio | | ratio | | ratio | Mw |
| Polymer-1 | ALU-1 | 20 | ALU-4 | 35 | Unit-1 | 20 | Unit-3 | 20 | Unit-4 | 5 | 4500 |
| Polymer-2 | ALU-1 | 30 | ALU-4 | 30 | Unit-1 | 20 | Unit-2 | 20 | | | 5500 |
| Polymer-3 | ALU-1 | 35 | ALU-5 | 25 | Unit-1 | 20 | Unit-3 | 10 | Unit-4 | 10 | 5000 |
| Polymer-4 | ALU-1 | 15 | ALU-6 | 35 | Unit-1 | 20 | Unit-2 | 15 | Unit-4 | 15 | 6000 |
| Polymer-5 | ALU-1 | 40 | ALU-7 | 30 | Unit-1 | 10 | Unit-3 | 10 | Unit-5 | 10 | 5500 |
| Polymer-6 | ALU- | 30 | ALU-8 | 30 | Unit-1 | 15 | Unit-3 | 15 | Unit-4 | 10 | 6000 |
| | 11 | | | | | | | | | | |
| Polymer-7 | ALU-1 | 40 | ALU-9 | 15 | Unit-1 | 25 | Unit-2 | 20 | | | 6500 |
| Polymer-8 | ALU-1 | 35 | ALU- | 30 | Unit-1 | 10 | Unit-3 | 10 | Unit-4 | 15 | 7000 |
| | | | 10 | | | | | | | | |
| Polymer-9 | ALU-2 | 40 | ALU-4 | 20 | Unit-1 | 15 | Unit-3 | 15 | Unit-4 | 10 | 7000 |
| Polymer- | ALU-2 | 10 | ALU-5 | 40 | Unit-1 | 15 | Unit-2 | 20 | Unit-4 | 15 | 6000 |
| 10 | | | | | | | | | | | |
| Polymer- | ALU-2 | 25 | ALU-6 | 40 | Unit-1 | 10 | Unit-3 | 15 | Unit-5 | 10 | 7000 |
| 11 | | | | | | | | | | | |
| Polymer- | ALU-2 | 30 | ALU-7 | 30 | Unit-1 | 25 | Unit-3 | 15 | | | 6500 |
| 12 | | | | | | | | | | | |
| Polymer- | ALU-2 | 25 | ALU-8 | 30 | Unit-1 | 20 | Unit-2 | 15 | Unit-4 | 10 | 5500 |
| 13 | | | | | | | | | | | |
| Polymer- | ALU-2 | 30 | ALU-9 | 40 | Unit-1 | 10 | Unit-3 | 10 | Unit-5 | 10 | 4500 |
| 14 | | | | | | | | | | | |
| Polymer- | ALU-2 | 10 | ALU- | 50 | Unit-1 | 20 | Unit-2 | 20 | | | 5000 |
| 15 | | | 13 | | | | | | | | |
| Polymer- | ALU-2 | 30 | ALU- | 20 | Unit-1 | 15 | Unit-3 | 15 | Unit-4 | 20 | 5500 |
| 16 | | | 10 | | | | | | | | |
| Polymer- | ALU- | 60 | Unit-1 | 15 | Unit-3 | 10 | Unit-5 | 15 | | | 6000 |
| 17 | 10 | | | | | | | | | | |
| Polymer- | ALU-4 | 65 | Unit-1 | 10 | Unit-2 | 15 | Unit-4 | 10 | | | 6500 |
| 18 | | | | | | | | | | | |
| Polymer- | ALU- | 35 | ALU-4 | 35 | Unit-1 | 15 | Unit-3 | 15 | | | 6500 |
| 19 | 12 | | | | | | | | | | |
| Polymer- | ALU-3 | 40 | ALU-5 | 25 | Unit-1 | 15 | Unit-3 | 20 | | | 5500 |
| 20 | | | | | | | | | | | |
| Polymer- | ALU-3 | 10 | ALU-6 | 50 | Unit-1 | 10 | Unit-2 | 15 | Unit-5 | 15 | 7000 |
| 21 | | | | | | | | | | | |
| Polymer- | ALU-3 | 30 | ALU-7 | 25 | Unit-1 | 10 | Unit-3 | 20 | Unit-4 | 15 | 5000 |
| 22 | | | | | | | | | | | |
| Polymer- | ALU-3 | 30 | ALU-8 | 35 | Unit-1 | 25 | Unit-3 | 10 | | | 4500 |
| 23 | | | | | | | | | | | |
| Polymer- | ALU-3 | 15 | ALU-9 | 35 | Unit-1 | 25 | Unit-3 | 15 | Unit-4 | 10 | 6500 |
| 24 | | | | | | | | | | | |
| Polymer- | ALU-3 | 45 | ALU- | 15 | Unit-1 | 15 | Unit-2 | 15 | Unit-5 | 10 | 5500 |
| 25 | | | 10 | | | | | | | | |
| Polymer- | ALU-1 | 40 | Unit-1 | 35 | Unit-4 | 25 | | | | | 6000 |
| 26 | | | | | | | | | | | |
| Polymer- | ALU-4 | 40 | Unit-3 | 35 | Unit-4 | 25 | | | | | 5000 |
| 27 | | | | | | | | | | | |
| Polymer- | ALU-2 | 30 | Unit-2 | 40 | Unit-5 | 30 | | | | | 5500 |
| 28 | | | | | | | | | | | |
| Polymer- | ALU-3 | 30 | ALU-9 | 30 | Unit-3 | 20 | Unit-6 | 20 | | | 6500 |
| 29 | | | | | | | | | | | |
| Polymer- | ALU-1 | 80 | Unit-1 | 20 | | | | | | | 6000 |
| 30 | | | | | | | | | | | |

TABLE 2

| | |
|---|---|
| 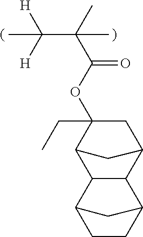 [SMILES: CCC(C)(C)C(=O)OC1(CC)CC2CC1C1C3CCC(C3)C21] | ALU-1 |
| 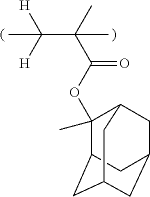 [SMILES: CCC(C)(C)C(=O)OC1(C)C2CC3CC(C2)CC1C3] | ALU-2 |
| 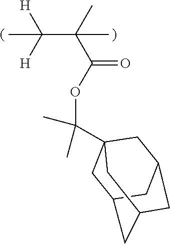 [SMILES: CCC(C)(C)C(=O)OC(C)(C)C12CC3CC(CC(C3)C1)C2] | ALU-3 |
| 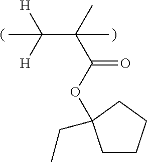 | ALU-4 |
| 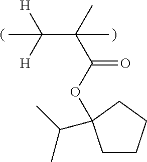 [SMILES: CCC(C)(C)C(=O)OC1(C(C)C)CCCC1] | ALU-5 |
| 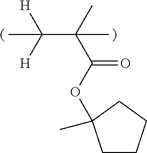 | ALU-6 |
| 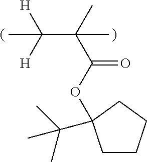 [SMILES: CCC(C)(C)C(=O)OC1(C(C)(C)C)CCCC1] | ALU-7 |
| 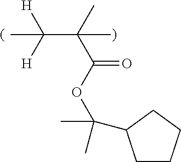 [SMILES: CCC(C)(C)C(=O)OC(C)(C)C1CCCC1] | ALU-8 |
| 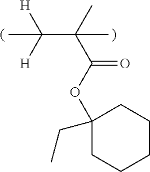 [SMILES: CCC1(OC(=O)C(C)(C)CC)CCCCC1] | ALU-9 |
| 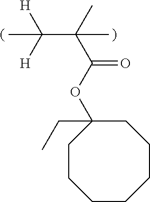 [SMILES: CCC1(OC(=O)C(C)(C)CC)CCCCCCC1] | ALU-10 |
| 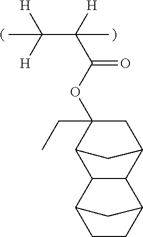 [SMILES: CCC(C)C(=O)OC1(CC)CC2CC1C1C3CCC(C3)C21] | ALU-11 |
| 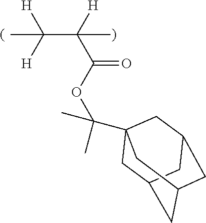 [SMILES: CCC(C)C(=O)OC(C)(C)C12CC3CC(CC(C3)C1)C2] | ALU-12 |
| 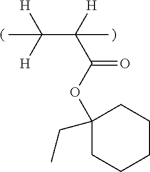 | ALU-13 |

TABLE 3

| | |
|---|---|
| 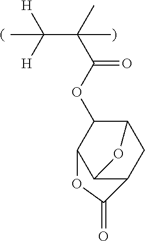 [SMILES: CCC(C)(C)C(=O)OC1C2CC3C(=O)OC1C3O2] | Unit-1 |
| 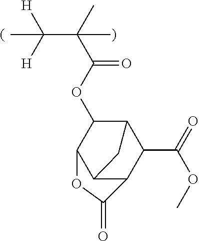 [SMILES: CCC(C)(C)C(=O)OC1C2CC3C1OC(=O)C3C2C(=O)OC] | Unit-2 |
| 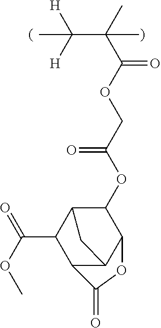 [SMILES: CCC(C)(C)C(=O)OCC(=O)OC1C2CC3C1OC(=O)C3C2C(=O)OC] | Unit-3 |
| 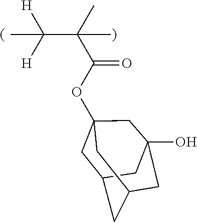 [SMILES: CCC(C)(C)C(=O)OC12CC3CC(CC(O)(C3)C1)C2] | Unit-4 |
| 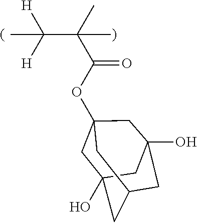 [SMILES: CCC(C)(C)C(=O)OC12CC3CC(O)(CC(O)(C3)C1)C2] | Unit-5 |
| 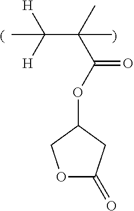 | Unit-6 |

### <Preparation of Positive Resist Compositions (PR01 to PR30)>

Then, in addition to the foregoing resins (polymers), various photo acid generators and various basic compounds (nitrogen-containing compounds) were dissolved into various solvents; and after dissolution of them, the resulting mixture was passed through a filter (pore size of 0.2 μm) made of Teflon (registered trade name) to obtain positive resist compositions of the present invention as shown in Table 4 (PR1 to PR16 and PR19 to PR25).

Resist compositions (PR17, PR18, and PR26 to PR30) were also prepared as comparative test samples. Structures of the photo acid generators in Table 4 are shown in Table 5; and structures of the basic compounds (nitrogen-containing compounds) used as quenchers are shown in Table 6.

TABLE 4

| | | Acid | Nitrogen- | |
|---|---|---|---|---|
| | Polymer | generator | containing | |
| Resist | (parts by | (parts by | compound | Solvent |
| composition | mass) | mass) | (parts by mass) | (parts by mass) |
| PR-1 | Polymer-1 | PAG-B1 | Q-C2 | PGMEA(1120) |
| | (80) | (6.8) | (0.3) | CyHO(480) |
| PR-2 | Polymer-2 | PAG-B2 | Q-C3 | PGMEA(1120) |
| | (80) | (7.6) | (0.3) | CyHO(480) |
| PR-3 | Polymer-3 | PAG-B3 | Q-C2 | PGMEA(1120) |
| | (80) | (8.4) | (0.3) | CyHO(480) |
| PR-4 | Polymer-4 | PAG-B2 | Q-C1 | PGMEA(1120) |
| | (80) | (7.6) | (0.4) | CyHO(480) |
| PR-5 | Polymer-5 | PAG-B1 | Q-C3 | PGMEA(1120) |
| | (80) | (6.8) | (0.3) | CyHO(480) |
| PR-6 | Polymer-6 | PAG-B4 | Q-C3 | PGMEA(1120) |
| | (80) | (10.2) | (0.3) | CyHO(480) |
| PR-7 | Polymer-7 | PAG-B3 | Q-C1 | PGMEA(1120) |
| | (80) | (8.4) | (0.4) | CyHO(480) |
| PR-8 | Polymer-8 | PAG-B1 | Q-C1 | PGMEA(1120) |
| | (80) | (6.8) | (0.4) | CyHO(480) |
| PR-9 | Polymer-9 | PAG-B4 | Q-C3 | PGMEA(1120) |
| | (80) | (10.2) | (0.3) | CyHO(480) |
| PR-10 | Polymer-10 | PAG-B2 | Q-C3 | PGMEA(1120) |
| | (80) | (7.6) | (0.3) | CyHO(480) |
| PR-11 | Polymer-11 | PAG-B1 | Q-C2 | PGMEA(1120) |
| | (80) | (6.8) | (0.3) | CyHO(480) |
| PR-12 | Polymer-12 | PAG-B3 | Q-C1 | PGMEA(1120) |
| | (80) | (8.4) | (0.4) | CyHO(480) |
| PR-13 | Polymer-13 | PAG-B2 | Q-C2 | PGMEA(1120) |
| | (80) | (7.6) | (0.3) | CyHO(480) |
| PR-14 | Polymer-14 | PAG-B2 | Q-C1 | PGMEA(1120) |
| | (80) | (7.6) | (0.4) | CyHO(480) |
| PR-15 | Polymer-15 | PAG-B4 | Q-C2 | PGMEA(1120) |
| | (80) | (10.2) | (0.3) | CyHO(480) |
| PR-16 | Polymer-16 | PAG-B2 | Q-C1 | PGMEA(1120) |
| | (80) | (7.6) | (0.4) | CyHO(480) |
| PR-17 | Polymer-17 | PAG-B1 | Q-C3 | PGMEA(1120) |
| | (80) | (6.8) | (0.3) | CyHO(480) |
| PR-18 | Polymer-18 | PAG-B3 | Q-C2 | PGMEA(1120) |
| | (80) | (8.4) | (0.3) | CyHO(480) |
| PR-19 | Polymer-19 | PAG-B4 | Q-C3 | PGMEA(1120) |
| | (80) | (10.2) | (0.3) | CyHO(480) |
| PR-20 | Polymer-20 | PAG-B1 | Q-C2 | PGMEA(1120) |
| | (80) | (6.8) | (0.3) | CyHO(480) |
| PR-21 | Polymer-21 | PAG-B2 | Q-C1 | PGMEA(1120) |
| | (80) | (7.6) | (0.4) | CyHO(480) |
| PR-22 | Polymer-22 | PAG-B3 | Q-C2 | PGMEA(1120) |
| | (80) | (8.4) | (0.3) | CyHO(480) |
| PR-23 | Polymer-23 | PAG-B3 | Q-C3 | PGMEA(1120) |
| | (80) | (8.4) | (0.3) | CyHO(480) |
| PR-24 | Polymer-24 | PAG-B1 | Q-C1 | PGMEA(1120) |
| | (80) | (6.8) | (0.4) | CyHO(480) |
| PR-25 | Polymer-25 | PAG-B2 | Q-C3 | PGMEA(1120) |
| | (80) | (7.6) | (0.3) | CyHO(480) |
| PR-26 | Polymer-26 | PAG-B2 | Q-C3 | PGMEA(1120) |
| | (80) | (7.6) | (0.3) | CyHO(480) |
| PR-27 | Polymer-27 | PAG-B1 | Q-C1 | PGMEA(1120) |
| | (80) | (6.8) | (0.4) | CyHO(480) |
| PR-28 | Polymer-28 | PAG-B4 | Q-C1 | PGMEA(1120) |
| | (80) | (10.2) | (0.4) | CyHO(480) |
| PR-29 | Polymer-29 | PAG-B3 | Q-C2 | PGMEA(1120) |
| | (80) | (8.4) | (0.3) | CyHO(480) |
| PR-30 | Polymer-30 | PAG-B4 | Q-C3 | PGMEA(1120) |
| | (80) | (10.2) | (0.3) | CyHO(480) |

TABLE 5

| | |
|---|---|
| 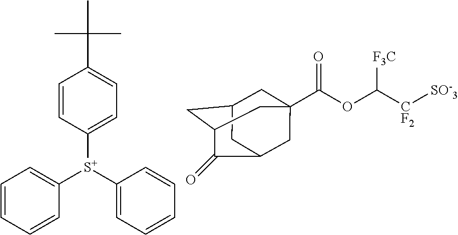 | PAG-B1 |
| 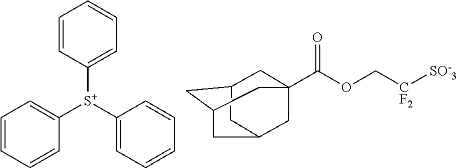 | PAG-B2 |
| 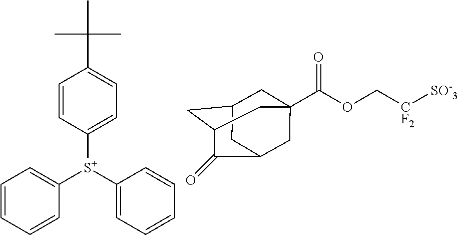 | PAG-B3 |
| 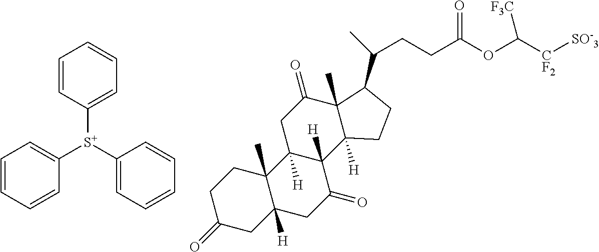 | PAG-B4 |

TABLE 6

| | |
|---|---|
| 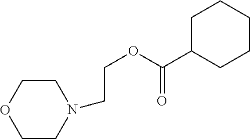 [SMILES: O=C(OCCN1CCOCC1)C1CCCCC1] | Q-C1 |
| 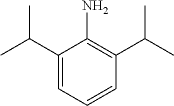 | Q-C2 |
| 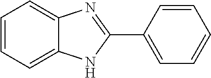 [SMILES: c1ccc(-c2nc3ccccc3[nH]2)cc1] | Q-C3 |

Solvents shown in Table 4 are as follows.

PGMEA: Propylene glycol monomethyl ether acetate

### CyHO: Cyclohexanone

In addition, an alkaline-soluble surfactant SF-1 (5.0 parts by mass) and surfactant A (0.1 parts by mass) were added into any of resist compositions shown in Table 4. Structure of the alkaline-soluble surfactant SF-1 and structure of the surfactant A are shown below. Alkaline-soluble surfactant SF-1: poly(methacrylic acid=3,3,3-trifluoro-2-hydroxy-1,1-dimethyl-2-trifluoromethylpropyl•methacrylic acid=1,1,1-trifluoro-2-hydroxy-6-methyl-2-trifluoromethylhepta-4-yl•methacrylic acid=7-(1,1,1,3,3,3-hexafluoroisopropoxycarbonyl)-2-oxohexahydro-3,5-methano-2H-cyclopenta[b]furane-6-yl) (see the following formula)

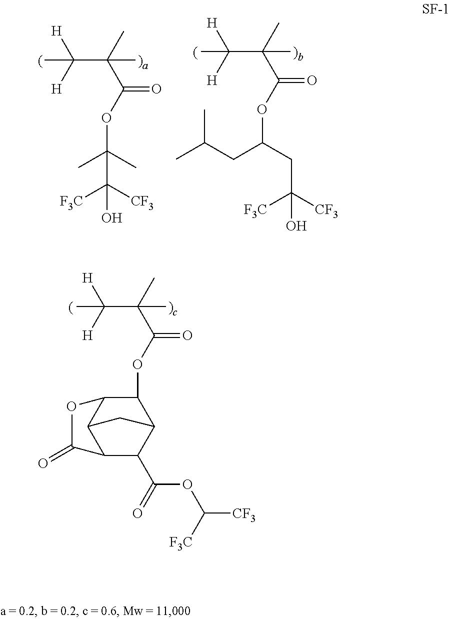

Surfactant A: 3-methyl-3-(2,2,2-trifluoroethoxymethyl) oxetane•tetrahydrofuran•2,2-dimethyl-1,3-propanediol copolymer (manufactured by Omnova Solutions, Inc.) (see the following formula)

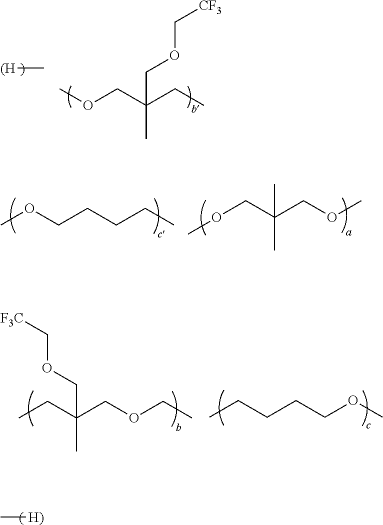

a:(b+b′):(c+c′)=1:4˜7:0.01˜1 (mole ratio)
Weight-average molecular weight: 1500

### <Evaluation Method: Examples 1 to 23 and Comparative Examples 1 to 7>

The resist solution prepared as mentioned above was applied onto the anti-reflective film (film thickness of 100 nm) formed on the substrate—which was prepared by applying a solution for an anti-reflective film (ARC-29A, manufactured by Nissan Chemical Industries, Ltd.) onto a silicon substrate followed by baking at 200° C. for 60 seconds—by spin coating, and then baked by using a hot plate at 100° C. for 60 seconds to obtain a resist film having film thickness of 150 nm.

Then, this was subjected to an immersion exposure by using an ArF excimer laser scanner (NSR-S610C, with NA of 1.30, σ of 0.94, 4/5 annular illumination, and 6% half tone phase shift, manufactured by Nikon Corp.), baked at an arbitrary temperature for 60 seconds (PEB), and then developed by a 2.38% by mass of aqueous tetramethyl ammonium hydroxide solution for 60 seconds to form a hole pattern.

Evaluation of the resist was made on a pattern of a 55-nm hole with a 110-nm pitch; and the exposure dose to give a hole with average diameter of 55 nm as observed by an electron microscope was taken as the optimum exposure dose (Eop, mJ/cm²).

The focal point at the optimum exposure dose was moved up and down whereby range of the focal point to resolve the foregoing hole pattern with the target size of 55 nm±10% (namely 49.5 to 60.5 nm) was obtained; and this was taken as the depth of focal point (DOF, nm).

Size variance of the diameter of the hole pattern having diameter of 55 nm formed with the foregoing optimum exposure dose (measured at 20 spots) was measured; and the 3σ value thereof was taken as the circularity barometer. When this value is small, circularity thereof is better.

Evaluation results of the resist compositions of the present invention shown in the above Table are shown in Table 7 (Examples 1 to 23). Evaluation results of the resist compositions for comparison are shown in Table 8 (Comparative Examples 1 to 7).

TABLE 7

| | | | Eop | | | |
|---|---|---|---|---|---|---|
| | Resist | PEB | (mJ/ | Pattern | DOF | Circularity |
| Example | composition | (° C.) | cm²) | Profile | (nm) | (nm) |
| Example-1 | PR-1 | 90 | 28 | Rectangular | 160 | 3.1 |
| | | | | profile | | |
| Example-2 | PR-2 | 90 | 26 | Rectangular | 180 | 3.2 |
| | | | | profile | | |
| Example-3 | PR-3 | 90 | 28 | Rectangular | 180 | 3.2 |
| | | | | profile | | |
| Example-4 | PR-4 | 95 | 38 | Rectangular | 120 | 3.5 |
| | | | | profile | | |
| Example-5 | PR-5 | 90 | 25 | Rectangular | 190 | 3.5 |
| | | | | profile | | |
| Example-6 | PR-6 | 100 | 33 | Rectangular | 170 | 3.2 |
| | | | | profile | | |
| Example-7 | PR-7 | 90 | 37 | Rectangular | 150 | 3.7 |
| | | | | profile | | |
| Example-8 | PR-8 | 85 | 28 | Rectangular | 180 | 3.2 |
| | | | | profile | | |
| Example-9 | PR-9 | 90 | 34 | Rectangular | 150 | 3.4 |
| | | | | profile | | |
| Example- | PR-10 | 90 | 33 | Rectangular | 120 | 3.3 |
| 10 | | | | profile | | |
| Example- | PR-11 | 95 | 31 | Rectangular | 180 | 3.2 |
| 11 | | | | profile | | |
| Example- | PR-12 | 90 | 29 | Rectangular | 180 | 3.1 |
| 12 | | | | profile | | |
| Example- | PR-13 | 100 | 30 | Rectangular | 160 | 3.4 |
| 13 | | | | profile | | |
| Example- | PR-14 | 90 | 27 | Rectangular | 190 | 3.4 |
| 14 | | | | profile | | |
| Example- | PR-15 | 90 | 31 | Rectangular | 160 | 3.5 |
| 15 | | | | profile | | |
| Example- | PR-16 | 85 | 38 | Rectangular | 130 | 3.6 |
| 16 | | | | profile | | |
| Example- | PR-19 | 90 | 30 | Rectangular | 180 | 3.3 |
| 17 | | | | profile | | |
| Example- | PR-20 | 90 | 28 | Rectangular | 180 | 3.3 |
| 18 | | | | profile | | |
| Example- | PR-21 | 95 | 31 | Rectangular | 180 | 3.2 |
| 19 | | | | profile | | |
| Example- | PR-22 | 90 | 28 | Rectangular | 170 | 3.2 |
| 20 | | | | profile | | |
| Example- | PR-23 | 100 | 27 | Rectangular | 180 | 3.4 |
| 21 | | | | profile | | |
| Example- | PR-24 | 90 | 35 | Rectangular | 120 | 3.5 |
| 22 | | | | profile | | |
| Example- | PR-25 | 85 | 29 | Rectangular | 180 | 3.1 |
| 23 | | | | profile | | |

TABLE 8

| | | | Eop | | | |
|---|---|---|---|---|---|---|
| Comparative | Resist | PEB | (mJ/ | Pattern | DOF | Circularity |
| example | composition | (° C.) | cm²) | Profile | (nm) | (nm) |
| Comparative | PR-26 | 90 | 48 | Rounding | 50.0 | 5.0 |
| example-1 | | | | profile | | |
| Comparative | PR-27 | 95 | 50 | Rounding | 60.0 | 4.8 |
| example-2 | | | | profile | | |
| Comparative | PR-28 | 100 | 55 | Rounding | 30.0 | 5.5 |
| example-3 | | | | profile | | |
| Comparative | PR-29 | 90 | 27 | Slightly | 90.0 | 4.6 |
| example-4 | | | | rounding | | |
| | | | | profile | | |
| Comparative | PR-30 | 90 | 25 | Large | 80.0 | 4.9 |
| example-5 | | | | head | | |
| | | | | profile | | |
| Comparative | PR-17 | 80 | 28 | Slightly | 170 | 3.3 |
| example-6 | | | | rounding | | |
| | | | | profile | | |
| Comparative | PR-18 | 95 | 26 | Slightly | 180 | 3.1 |
| example-7 | | | | rounding | | |
| | | | | profile | | |

From the results of Examples 1 to 23 in Table 7 and the results of Comparative Examples 1 to 7 shown in Table 8, the positive resist compositions of the present invention (PR1 to PR16 and PR19 to PR25) using Polymer-1 to Polymer-16 and Polymer-19 to Polymer-25, which contain the repeating unit shown by the general formula (1-1), the repeating unit shown by the general formula (1-2), at least one repeating unit shown by the general formula (a-1) to (a-3), and at least one repeating unit shown by the general formula (b-1) and (b-2), showed excellent performances in pattern profile, circularity, and BOF in the contact hole pattern as compared with the resist compositions used as comparative samples (PR17, PR18, and PR26 to PR-30) which use Polymer-17, Polymer-18, and Polymer-26 to Polymer-30.

The present invention is not limited to the embodiment described above. The above-described aspects are mere examples and those having substantially the same structure as technical ideas described in the appended claims and providing the similar functions and advantages are included in the scope of the present invention.

What is claimed is:

1. A positive resist composition comprising (A) a resin having an alkaline-solubility thereof increased by an acid and containing a repeating unit shown by the following general formula (1-1), a repeating unit shown by the following general formula (1-2), and as repeating units having an acid labile group, at least one repeating unit shown by the following general formulae (a-1) to (a-3) and at least one repeating unit shown by the following general formulae (b-1) and (b-2), (B) a photo acid generator, (C) a basic compound, and (D) a solvent, 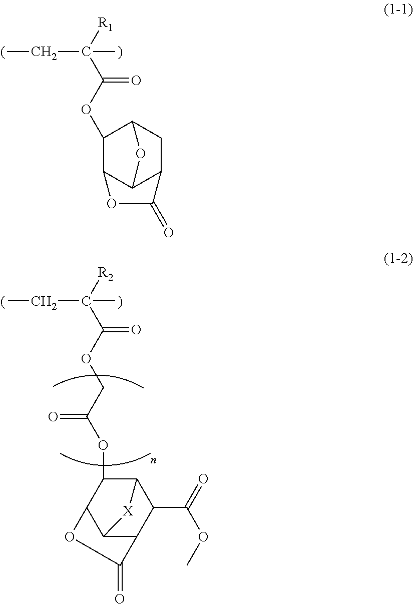
wherein R₁ and R₂ represent a methyl group or a hydrogen atom; X represents any of an oxygen atom, a sulfur atom, a methylene group, and an ethylene group; “n” represents 0 or 1; 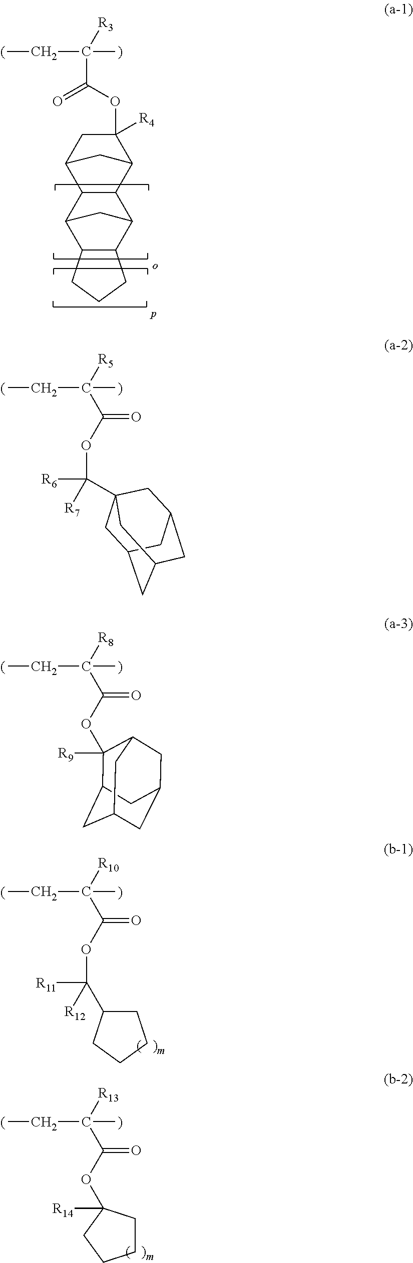
wherein R₃, R₅, R₈, R₁₀, and R₁₃ represent a methyl group or a hydrogen atom; R₄, R₈, R₇, R₈, R₁₁, R₁₂, and R₁₄ represent a linear or a branched alkyl group having 1 to carbon atoms; “o” and “p” represent o=1 and p=0, or o=0 and p=1; and “m” represents an integer of 1 to 4.

2. The positive resist composition according to claim 1, wherein the repeating units having an acid labile group and contained in (A) the resin having an alkaline-solubility thereof increased by an acid are a repeating unit shown by the following general formula (a-1)′ and a repeating unit shown by the following general formula (b-2), wherein R₃, R₁₃, R₄, R₁₄, and “m” represent the same meanings as before.

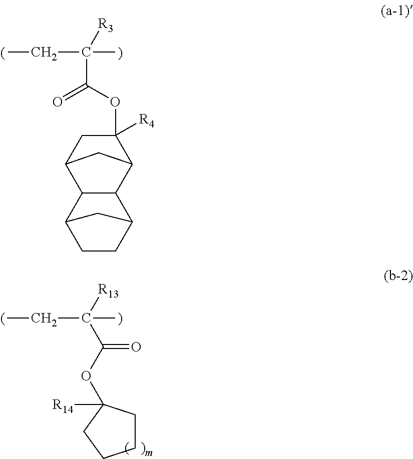

3. The positive resist composition according to claim 1, wherein (A) the resin having an alkaline-solubility thereof increased by an acid further contains a repeating unit shown by the following general formula (2), wherein R₁₅ represents a methyl group or a hydrogen atom; Y represents a single bond or a divalent organic group optionally containing at least either one of an ester bond and an ether bond; and “l” represents 1 or 2.

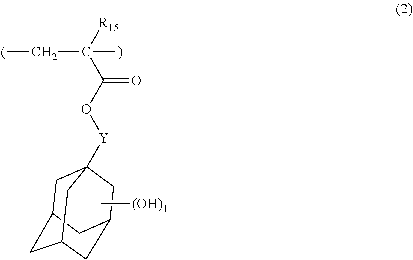

4. The positive resist composition according to claim 2, wherein (A) the resin having an alkaline-solubility thereof increased by an acid further contains a repeating unit shown by the following general formula (2), wherein R₁₅ represents a methyl group or a hydrogen atom; Y represents a single bond or a divalent organic group optionally containing at least either one of an ester bond and an ether bond; and “1” represents 1 or 2.

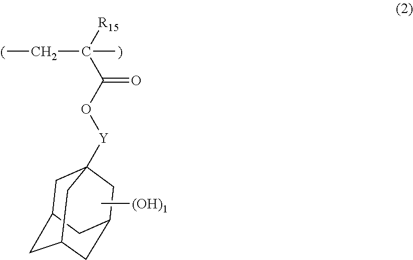

5. The positive resist composition according to claim 1, wherein amount of the repeating units having an acid labile group in (A) the resin having an alkaline-solubility thereof increased by an acid is 50 to 70% by mole relative to totality of the repeating units contained in (A) the resin having an alkaline-solubility thereof increased by an acid.

6. The positive resist composition according to claim 2, wherein amount of the repeating units having an acid labile group in (A) the resin having an alkaline-solubility thereof increased by an acid is 50 to 70% by mole relative to totality of the repeating units contained in (A) the resin having an alkaline-solubility thereof increased by an acid.

7. The positive resist composition according to claim 3, wherein amount of the repeating units having an acid labile group in (A) the resin having an alkaline-solubility thereof increased by an acid is 50 to 70% by mole relative to totality of the repeating units contained in (A) the resin having an alkaline-solubility thereof increased by an acid.

8. The positive resist composition according to claim 4, wherein amount of the repeating units having an acid labile group in (A) the resin having an alkaline-solubility thereof increased by an acid is 50 to 70% by mole relative to totality of the repeating units contained in (A) the resin having an alkaline-solubility thereof increased by an acid.

9. A patterning process wherein the process includes a step of applying the positive resist composition according to claim 1 onto a substrate; after heat treatment, a step of exposure to a high energy beam; and a step of development by using an alkaline developer.

10. A patterning process wherein the process includes a step of applying the positive resist composition according to claim 8 onto a substrate; after heat treatment, a step of exposure to a high energy beam; and a step of development by using an alkaline developer.

11. The patterning process according to claim 9, wherein wavelength of the high energy beam is in the range of 180 to 250 nm.

12. The patterning process according to claim 10, wherein wavelength of the high energy beam is in the range of 180 to 250 nm.

13. The patterning process according to claim 9, wherein the step of exposure to the high energy beam is carried out by an immersion exposure in which the exposure is done via water.

14. The patterning process according to claim 10, wherein the step of exposure to the high energy beam is carried out by an immersion exposure in which the exposure is done via water.

15. The patterning process according to claim 11, wherein the step of exposure to the high energy beam is carried out by an immersion exposure in which the exposure is done via water.

16. The patterning process according to claim 12, wherein the step of exposure to the high energy beam is carried out by an immersion exposure in which the
